(19) United States
(12) Patent Application Publication
(10) Pub. No.: US 2025/0231285 A1
(43) Pub. Date: Jul. 17, 2025

(54) PHOTOELECTRIC PACKAGING STRUCTURE, PREPARATION METHOD AND CAMERA MODULE

(71) Applicant: TRIPLE WIN TECHNOLOGY(SHENZHEN) CO.LTD., Shenzhen (CN)

(72) Inventors: Hsin-Yen HSU, New Taipei (TW); Tzu-Li FENG, New Taipei (TW)

(21) Appl. No.: 19/016,154

(22) Filed: Jan. 10, 2025

(30) Foreign Application Priority Data
Jan. 16, 2024 (CN) 202410061596.X

(51) Int. Cl. G01S 7/481; G01S 17/894; H10F 55/25; H10F 77/00

(52) U.S. Cl. CPC G01S 7/4811; G01S 17/894; H10F 55/25; H10F 77/93

(57) ABSTRACT

A packaging structure, a preparation method, and a camera module are provided. The packaging structure includes a substrate module, and a light emitting unit and a light receiving unit located on the substrate of the substrate module. The substrate module defines first channels and second channels. Two ends of each first channel extend to the substrate and the non-photosensitive area of the light receiving unit, respectively. A first conductive layer is formed on an inner wall of each first channel to form a first hollow conductive channel, which is electrically connected to the substrate and the non-photosensitive area. Two ends of each second channel extend to the substrate and the light emitting unit, respectively. A second conductive layer is formed on an inner wall of each second channel to form a second hollow conductive channel, which is electrically connected to the substrate and the light emitting unit.

### FIELD

The subject matter herein generally relates to semiconductor packages, and more particularly, to a photoelectric packaging structure, and a preparation method of the packaging structure, and a camera module having the packaging structure.

### BACKGROUND

Camera modules (such as TOF cameras) may include a substrate, a light emitter mounted on the substrate, and a light receiver mounted on the substrate. In the camera module, the light emitter emits infrared light towards a target object. The light is reflected by the object toward the light receiver. By calculating a difference of the time at which the light is emitted and the time at which the light is received, a set of depth data is obtained, which may be used to determine the three-dimensional structure or contour of the target object.

The substrate and the light receiver or the light emitter are electrically connected to each other through a wire bonding packaging technology or flip chip packaging technology. However, in the wire bonding packaging, since a certain space may be required for operating a wire bonding tool, a connection path between the substrate and the light receiver or the light emitter may be long, which is not conducive to the miniaturization of the packaging structure. The flip chip packaging technology requires the substrate to have a high flatness and symmetrically distributed solder joints, such that the flip chip packaging technology has a low universality. Improvements in the art are desired.

### BRIEF DESCRIPTION OF THE DRAWINGS

FIG. 1 is a diagrammatic view of a camera module according to an embodiment of the present disclosure.

FIG. 2 is a diagrammatic view of a packaging structure of the camera module of FIG. 1.

FIG. 3 is a diagrammatic view of the packaging structure according to another embodiment.

FIG. 4 is a diagrammatic view of the packaging structure according to yet another embodiment.

FIG. 5 is a diagrammatic view of the packaging structure according to yet another embodiment.

FIG. 6 is a top view of a board according to an embodiment of the present disclosure.

FIG. 7 is a diagrammatic view showing a second plastic encapsulation block formed on a light receiving unit and a driving chip according to an embodiment of the present disclosure.

FIG. 8 is a diagrammatic view showing the board of FIG. 6 stacked on a structure of FIG. 7 to obtain an intermediate body.

FIG. 9 is a diagrammatic view showing the intermediate body of FIG. 8 pressed together.

FIG. 10 is a diagrammatic view showing channels defined in the plastic encapsulation body of FIG. 9.

FIG. 11 is a diagrammatic view showing a conductive layer formed in the channel of FIG. 10.

FIG. 12 is a diagrammatic view of a packaging structure according to another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

In the wire bonding packaging technology, metal wires are used to connect the substrate to the light emitter or light receiver, thereby achieving the electrical connection between the substrate and the light emitter or light receiver. However, the wire bonding packaging technology requires an operation space for the wire bonding tool, resulting in a large lateral distance from the substrate to the light emitter or light receiver, which is not conducive to the miniaturization of the packaging structure. Also, the metal wires are thin and brittle, such that other components cannot be installed inside the space occupied by the metal wires.

In the flip chip packaging technology, metal balls or metal posts are used to connect the substrate to the light emitter or light receiver, thereby achieving the electrical connection between the substrate and the light emitter or light receiver. In the flip chip packaging process, due to the size limitation of the metal balls, a high flatness of the substrate is required. Furthermore, when the light emitter or light receiver is soldered to the substrate, to allow all solder points of the chip to be simultaneously soldered to the substrate, the solder points need to be symmetrically distributed. As such, when pressure or ultrasonic energy is applied onto the light emitter or light receiver, the energy may be uniformly transferred to the light emitter or light receiver. Thus, the flip chip packaging technology has a low universality.

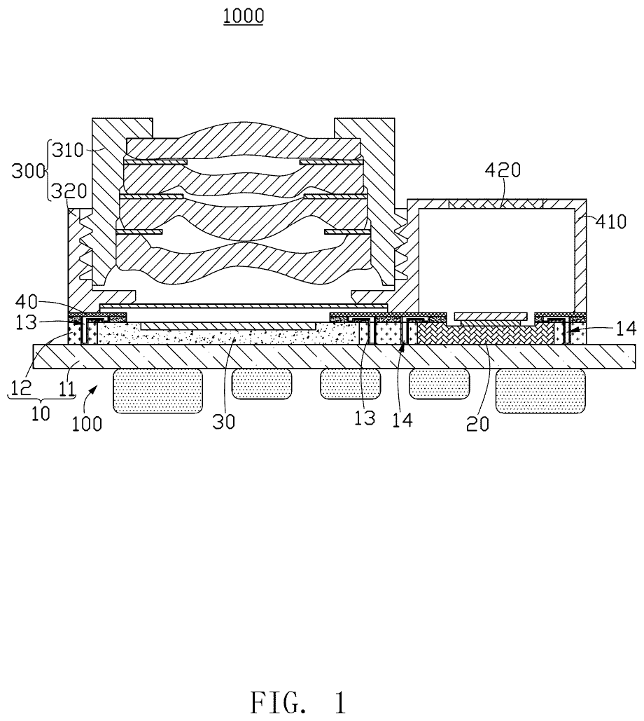

Referring to FIG. 1, a camera module 1000 is provided according to an embodiment of the present disclosure. The camera module 1000 includes a packaging structure 100 and a lens assembly 300. The packaging structure 100 may be applied in fields such as motion control, artificial intelligence, and machine vision. In the embodiment, the packaging structure 100 is applied to a camera module, such as a TOF camera.

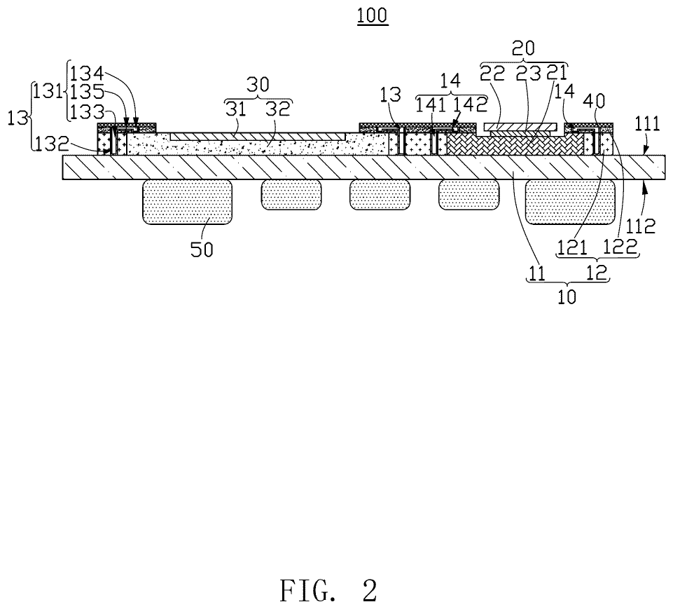

Referring to FIGS. 1 and 2, the packaging structure 100 includes a substrate module 10, a light emitting unit 20, and a light receiving unit 30. The substrate module 10 includes a substrate 11. The light emitting unit 20 and the light receiving unit 30 are located on the substrate 11. The lens assembly 300 is mounted on the substrate module 10 and faces the light receiving unit 30. The light emitting unit 20 emits the light beam toward the target object. The emitted light is reflected by the target object, and passes through the lens assembly 300 and received by the light receiving unit 30. By calculating a difference of the time at which the light is emitted and the time at which the light is received, a set of depth data is obtained, which may be used to determine the three-dimensional structure or contour of the target object. In another embodiment, a difference in phase of the light transmitted among the light emitting unit 20, the target object, and the light receiving unit 30 is also calculated, which may be used to determine the three-dimensional structure or contour of the target object.

Referring to FIGS. 1 and 2, the substrate module 10 defines a plurality of first channels 131 and a plurality of second channels 141. The light receiving unit 30 includes a photosensitive area 31 and a non-photosensitive area 32 connected to the photosensitive area 31. The non-photosensitive area 32 may surround the photosensitive area 31. The light receiving unit 30 includes a photosensitive chip. Two ends of each of the first channels 131 extend to the substrate 11 and the non-photosensitive area 32, respectively. A first conductive layer 132 is formed on an inner wall of the first channel 131, thereby forming a first hollow conductive channel 13. The first hollow conductive channel 13 is electrically connected to the substrate 11 and the non-photosensitive area 32. Two ends of each of the second channels 141 extend to the substrate 11 and the light emitting unit 20, respectively. A second conductive layer 142 is formed on an inner wall of the second channel 141, thereby forming a second hollow conductive channel 14. The second hollow conductive channel 14 is electrically connected to the substrate 11 and the light emitting unit 20.

In the present disclosure, the first hollow conductive channel 13 and the second hollow conductive channel 14 replace the existing metal wires. The settings of the first hollow conductive channel 13 and the second hollow conductive channel 14 do not require an operation space for the wire bonding tool. Thus, the lateral path between the substrate 10 and the non-photosensitive area 32 may be shortened without the limitation by the wire bonding tool, and the lateral path between the substrate 10 and the light emitting unit 20 may also be shortened without the limitation by the wire bonding tool. Moreover, since the shape of the first channel 131 and the second channel 141 may be changed according to the installation position of other components, the thickness of the packaging structure 1000 may also be reduced to a certain extent. Since the metal wires are not needed in the present disclosure, the installation positions of other components will not be limited around the metal wires due to the brittleness of the metal wires, thereby facilitating the miniaturization of the packaging structure 100.

Meanwhile, compared to the flip chip packaging technology, the present disclosure forms the first conductive layer 132 on the inner wall of the first channel 131 to obtain the first hollow conductive channel 13, and forms the second conductive layer 142 on the inner wall of the second channel 141 to form the second hollow conductive channel 14. Therefore, the package of the substrate module 10, the light emitting unit 20, and the light receiving unit 30 will not be limited by the size of the solder balls or by using symmetrically distributed solder joints. Thus, a high and strict flatness of the substrate module 10 will not be need in the present disclosure.

Referring to FIG. 1, the substrate module 10 further includes a plastic encapsulation body 12. The plastic encapsulation body 12 is located on the substrate 11, and at least adhered to the sidewall of the light receiving unit 30. The plastic encapsulation body 12 improves the stability of the packaging structure 100.

The lens assembly 300 includes at least one lens 310 and a lens holder 320. The lens holder 320 is mounted on the plastic encapsulation body 12. The at least one lens 310 is mounted in the lens holder 320. The light reflected by the tested object enters the camera module 1000 through the at least one lens 310. In some embodiment, the lens assembly 300 includes a number of lenses 310 stacked on each other, and the light passes through the lenses 310 and is then received by the light receiving unit 30. In other embodiments, the lens holder 320 may also be located on the substrate 11. When the lens holder 320 is located on the plastic encapsulation body 12, the lateral size of the camera module 1000 may be reduced.

Referring to FIG. 1, a base 410 and an optical lens 420 are also located on the substrate module 10. The optical lens 420 is mounted on the base 410 and located on a light emission path of the light emitting unit 20. In some embodiments, the base 410 is located on the substrate 11 or the plastic encapsulation body 12. When the base 410 is located on the plastic encapsulation body 12, the lateral size of the camera module 1000 may further be reduced, which is conducive to the miniaturization of the camera module 1000.

Referring to FIGS. 1 and 2, the light emitting unit 20 includes a driving chip 21 and a light source 22 located on the driving chip 21. The driving chip 21 is electrically connected to the light source 22. The plastic encapsulation body 12 is further adhered to the sidewall of the driving chip 21. The embodiment takes the base 410 being located on the plastic encapsulation body 12 for example. The base 410 and the substrate module 10 cooperatively define a cavity, and the light emitting unit 20 is located in the cavity. The optical lens 420 is located on a side of the base 410 away from the substrate 11. The optical lens 420 may be a transparent glass, a diffuser lens, a converging lens, and any combination thereof. The diffuser lens is used to adjust the travelling angle of the light emitted by the light source 22, and the converging lens is used to converge the light emitted by the light source 22. The light emitted by the light source 22 passes through the optical lens 420 and is directed towards the target object.

In some embodiments, the light source 22 may be a vertical cavity surface emitting laser (VCSEL) or a vertical external cavity surface emitting semiconductor laser (VECSEL). The driving chip 21 may be a laser ranging chip. The driving chip 21 is located below the light source 22, and is used to output signals to drive the light source 22 to emit light. In some embodiments, there is also an electrical connection portion 23 between the driving chip 21 and the light source 22. The light source 22 is electrically connected to the driving chip 21 through the electrical connection portion 23. The electrical connection portion 23 may be made of a conductive adhesive or a solder paste.

In some embodiments, the second hollow conductive channel 14 electrically connects the substrate 11 to the driving chip 21. Both of the first hollow conductive channel 13 and the second hollow conductive channel 14 are defined in the substrate 11 or the plastic encapsulation body 12. The substrate 11 includes a first surface 111 and a second surface 112 opposite to each other. The plastic encapsulation body 12, the driving chip 21, and the light receiving unit 30 are located on the same surface of the substrate 11.

In some embodiments, the first hollow conductive channel 13 at least partially extends along the thickness direction of the packaging structure 100, and the second hollow conductive channel 14 at least partially extends along the thickness direction of the packaging structure 100, thereby facilitating the drilling of the channels and the formation of the conductive layer within the channel. In some embodiments, the conductive ink is sprayed onto the inner wall of the channel and solidified to form the conductive layer.

The packaging structure 100 will further be described as follows, when both of the light receiving unit 30 and the light emitting unit 20 are located on the first surface 111 or the second surface 112, respectively.

### First Embodiment

Referring to FIG. 2, in the embodiment, both of the light emitting unit 20 and the light receiving unit 30 are located on the first surface 111. Each of the first channel 131 and the second channel 141 is defined in the plastic encapsulation body 12. The first channel 131 includes a first portion 133, a second portion 134, and a third portion 135 connected between the first portion 133 and the second portion 134. Each of the first portion 133 and the second portion 134 extends along the thickness of the plastic encapsulation body 12. Each of the first portion 133 and the second portion 134 is in the shape of a through hole. One end of the first portion 133 is sealed by the substrate 11, and the solder pad (not shown) of the substrate 11 is exposed from the first channel 131, thereby achieving the electrical connection between the first portion 133 and the solder pad. One end of the second portion 134 is sealed by the non-photosensitive area 32, and the solder pad (not shown) of the non-photosensitive area 32 is exposed from the first channel 131, thereby achieving the electrical connection between the second portion 134 and the pad. In the embodiment, the pad of the non-photosensitive area 32 is located on the surface of the light receiving unit 30 away from the substrate 11.

In some embodiments, the plastic encapsulation body 12 serves as a carrier for the first hollow conductive channel 13 and the second hollow conductive channel 14. The shape and position of each of the first channel 131 and the second hollow conductive channel 14 may be adjusted according to actual needs, thereby adjusting the shape and position of the first hollow conductive channel 13 and the second channel 141.

Referring to FIG. 2, in some embodiments, the plastic encapsulation body 12 includes a first plastic encapsulation block 121 and a second plastic encapsulation block 122 located on the first plastic encapsulation block 121. The first plastic encapsulation block 121 and the second plastic encapsulation block 122 are bonded and fixed to each other. The first plastic encapsulation block 121 is adhered to the sidewalls of the light receiving unit 30 and the driving chip 21. The second plastic encapsulation block 122 at least covers the non-photosensitive area 32 and a portion of the top surface of the driving chip 21 away from the substrate 11. The first portion 133 extends through the first plastic encapsulation block 121 and the second plastic encapsulation block 122. The second portion 134 extends through the second plastic encapsulation block 122.

In some embodiments, the third portion 135 is exposed from the second plastic encapsulation block 122. The third portion 135 is located on the top surface of the second plastic encapsulation block 122 or recessed from the top surface of the second plastic encapsulation block 122. When the third portion 135 is located on the top surface of the second plastic encapsulation block 122, a portion of the conductive layer is laid flat on the second plastic encapsulation block 122 and electrically connected to the conductive layers inside the first portion 133 and the second portion 134, respectively, thereby forming the first conductive layer 132. The second channel 141 may also have the same shape as the first channel 131.

When the third portion 135 is a groove structure recessed from the top surface of the second plastic encapsulation block 122, the opening of the groove faces away from the first plastic encapsulation block 121. When the third portion 135 is a groove structure, it facilitates the subsequent spraying of the conductive ink onto the inner wall of the third portion 135, and the conductive material is solidified to form the conductive layer. The groove structure also facilitates the spraying of the conductive ink onto the inner wall of the entire first channel 131 along a horizontal direction perpendicular to the thickness direction of the packaging structure 1000.

The second plastic encapsulation block 122 may function a carrier for the second portion 134 and the third portion 135. Since the plastic encapsulation body 12 includes the first plastic encapsulation block 121 and the second plastic encapsulation block 122, during the packaging process, the second plastic encapsulation block 122 may first cover the non-photosensitive area 32 and the driving chip 21, and then the first plastic encapsulation block 121 is adhered to the sidewalls of the light receiving unit 30 and the driving chip 21, which facilitates the assembly of the plastic encapsulation body 12 and improves the yield of the packaging structure 100. In other embodiments, the light receiving unit 30 and the driving chip 21 may be mounted on the substrate 11, and then the plastic encapsulation body 12 may also be integrally formed by injection molding on the substrate 11.

In some embodiments, the structures of the first hollow conductive channel 13 and the second hollow conductive channel 14 are similar. The steps of forming the first hollow conductive channel 13 and the second hollow conductive channel 14 may be simultaneously performed. For example, the first channel 131 and the second channel 141 with a same structure may be simultaneously formed, and the first conductive layer 132 and the second conductive layer 142 may be simultaneously formed, such as by spraying conductive material in the first channel 131 and the second channel 141. Thus, the steps of obtaining the first hollow conductive channel 13 and the second hollow conductive channel 14 are simplified. In other embodiments, the shapes of the first channel 131 and the second channel 141 may also be adjusted, thereby allowing the first hollow conductive channel 13 and the second hollow conductive channel 14 to have different structure.

In some embodiments, to avoid short circuits caused by electrical connection of the conductive layer, which is located in the third portion 135 and exposed from the second plastic encapsulation block 122, to other functional components, a protective film 40 is further formed on the second plastic encapsulation block 122. The protective film 40 covers the third portion 135. In some embodiments, the protective film 40 is formed to the entire surface of the second plastic encapsulation block 122, and also covers a portion of the second hollow conductive channel 14 exposed from the second plastic encapsulation block 122. The protective film 40 may include an ultraviolet adhesive.

The conductive material of each of the first conductive layer 132 and the second conductive layer 142 may include a conductive ink or a conductive silver paste. The conductive ink may be free of particles. The conductive ink may also include at least one element from silver, platinum, gold, copper, nickel, and aluminum.

In some embodiments, the packaging structure 100 further includes a number of electronic components 50. The electronic component 50 may be a passive component or an active component. The passive component includes a resistor or a capacitor. The active component includes a transistor, an integrated circuit, or a picture tube.

In some embodiments, the electronic components 50 are located on the second surface 112 of the substrate 11.

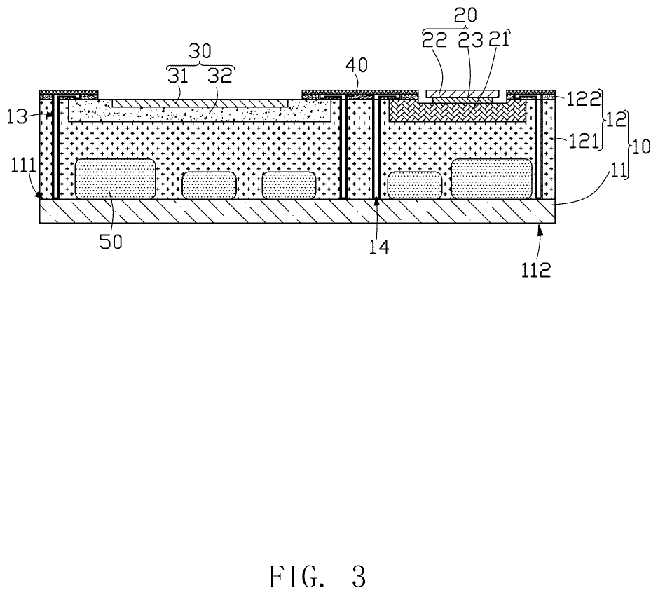

Referring to FIG. 3, in other embodiments, the electronic components 50 may also be located on the first surface 111 of the substrate 11 and embedded in the first plastic encapsulation block 121. A portion of the electronic components 50 is sealed between the light receiving unit 30 and the substrate 11, and another portion of the electronic components 50 is sealed between the driving chip 21 and the substrate 11. The first plastic encapsulation block 121 is located between the light receiving unit 30 and the substrate 11, and extends out of the light receiving unit 30 to wrap around the sidewalls of the light receiving unit 30 and the driving chip 21, thereby improving the stability of the light receiving unit 30, the driving chip 21, and the electronic components 50.

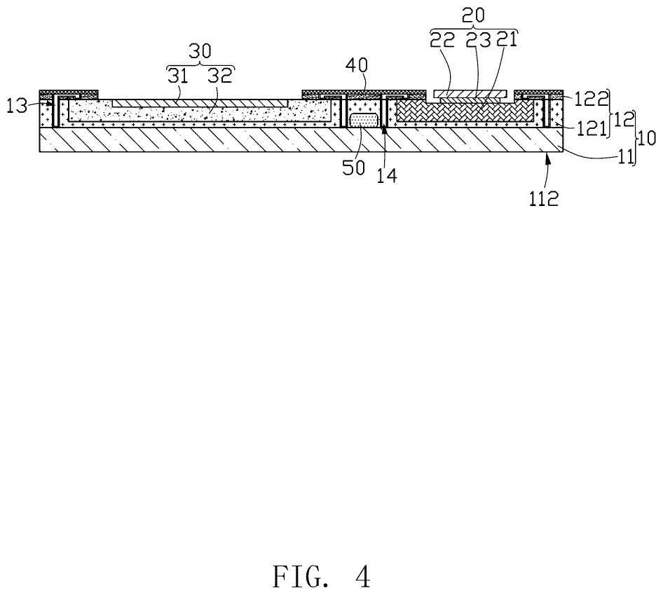

Referring to FIG. 4, in other embodiments, the electronic components 50 is located on one side of the light receiving unit 30 and embedded in the first plastic encapsulation block 121. The electronic component 50 is located between the light receiving unit 30 and the driving chip 21.

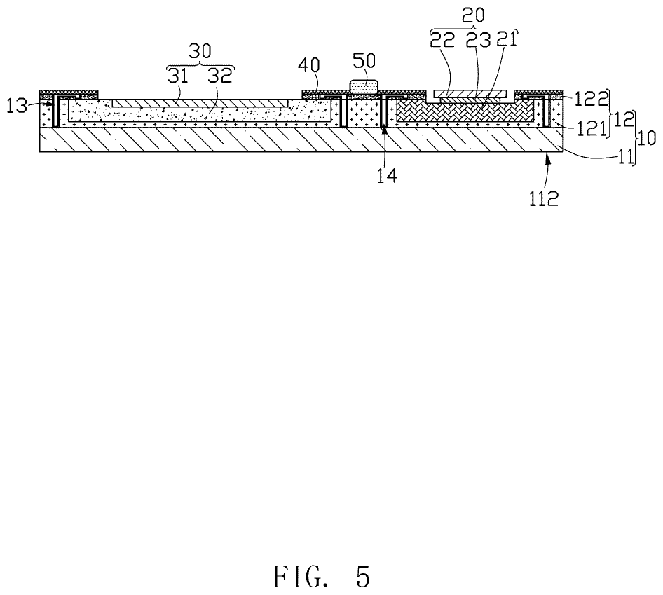

Referring to FIG. 5, in other embodiments, the electronic component 50 is located on one side of the light receiving unit 30 and on the plastic encapsulation body 12. The electronic component 50 is not embedded in the plastic encapsulation body 12.

In some embodiments, a thickness of the first conductive layer 132 is greater than or equal to 500 nm, and a thickness of the second conductive layer 142 is also greater than or equal to 500 nm. In some embodiments, the conductive layer is made of a conductive ink. The conductive ink is sprayed onto the inner wall of the channel and solidified to obtain the thickness described. In some embodiments, the thickness of the conductive layer may also be varied according to actual needs, such that the impedance of the conductive layer may be adjusted.

The packaging structure 100 of the present disclosure has a flat surface, which facilitates the installation of the lens assembly 300 on the surface of the packaging structure 100. A difference between the total length of the packaging structure 100 and the length of the light receiving unit 30 may be less than 500 μm, and a difference between the total width of the packaging structure 100 and the width of the light receiving unit 30 may be less than 500 μm. At the same time, the surface area of the packaging structure 100 is smaller than that of the packaging structures prepared by the wire bonding packaging technology and flip chip packaging technology, and the thickness of the packaging structure 100 is smaller than that of the packaging structure prepared by the flip chip packaging technology.

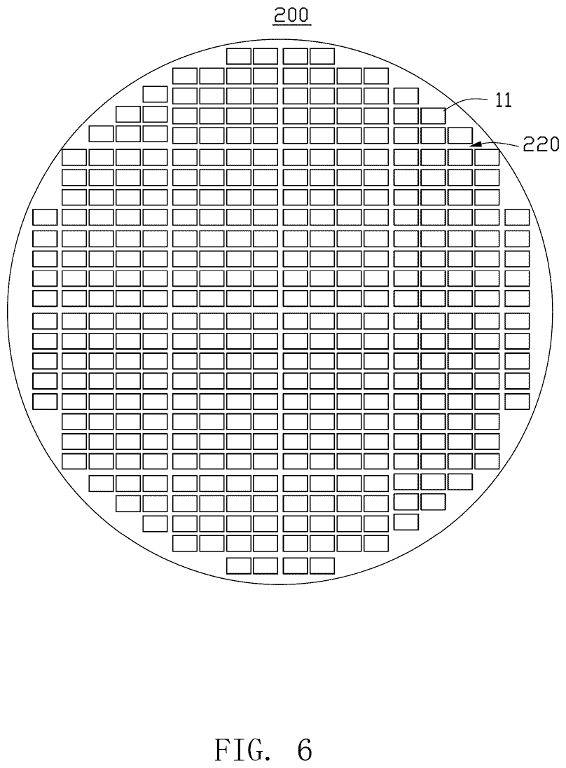

FIGS. 6 to 11 illustrate a preparation method of the packaging structure 100 in accordance with an embodiment. The method is provided by way of embodiments, as there are a variety of ways to carry out the method. The method can begin at step S1.

Step S1, referring to FIG. 6, a board 200 is provided, which includes a number of substrates 11 arranged in arrays. Adjacent two substrates 11 form a cutting area 220 therebetween.

Step S2, referring to FIG. 6, each substrate 11 is fabricated into a packaging unit 210. The fabrication of the package unit 210 may be carried out by the following steps.

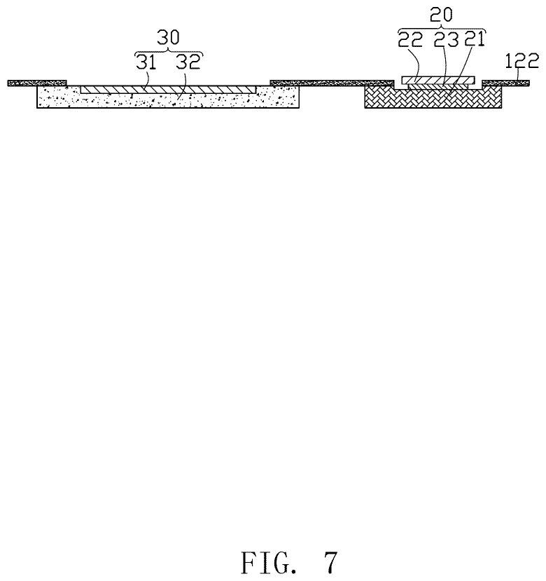

(1) Referring to FIG. 7, the second plastic encapsulation block 122 is formed on the non-photosensitive area 32 of the light receiving unit 30 and the driving chip 21 of the light emitting unit 20.

The light receiving unit 30 includes a photosensitive area 31 and a non-photosensitive area 32 connected to the photosensitive area 31. The second plastic encapsulation block 122 may be formed on the light receiving unit 30 and the driving chip 21 by gluing. A portion of the second plastic encapsulation block 122 is formed on the light receiving unit 30, and another portion of the second plastic encapsulation block 122 is formed on the driving chip 21. The driving chip 21 and the light receiving unit 30 are located on the same surface of the second plastic encapsulation block 122, leaving a gap being formed between the driving chip 21 and the light receiving unit 30.

The light emitting unit 20 includes a driving chip 21 and a light source 22 located on the driving chip 21. The driving chip 21 and the light source 22 are electrically connected to each other. Before the second plastic encapsulation block 122 is formed on the driving chip 21, the light source 22 is assembled onto the driving chip 21.

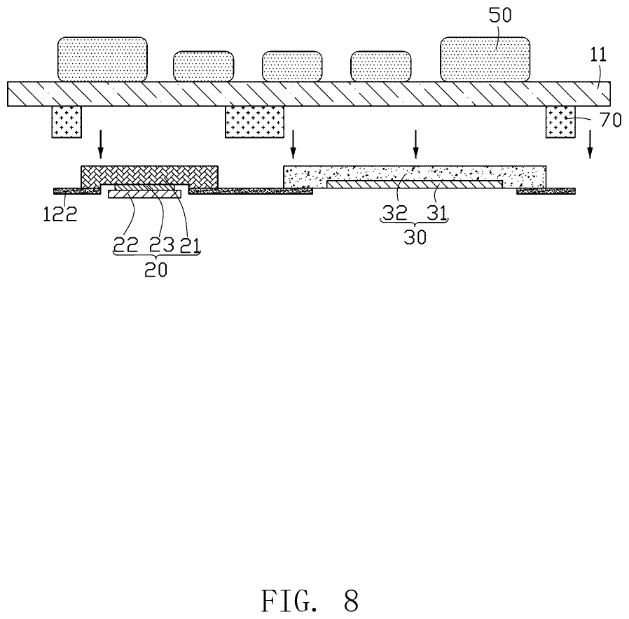

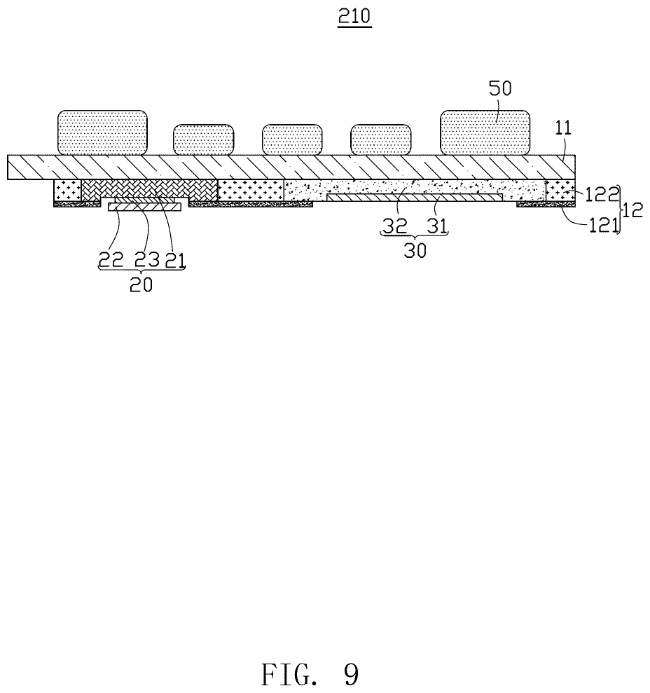

(2) Referring to FIGS. 8 and 9, the light receiving unit 30 with the second plastic encapsulation block 122 and the driving chip 21 are pressed and fixed onto one substrate 11. The substrate 11 also includes a plastic encapsulation preform 70 thereon. The plastic encapsulation preform 70 is at least adhered to the sidewalls of the light receiving unit 30 and the driving chip 21.

At the same time, a portion of the plastic encapsulation preform 70 is located between the light receiving unit 30 and the driving chip 21.

The light receiving unit 30 and the driving chip 21 may be adhered to the substrate 11 through an insulating adhesive layer. The plastic encapsulation preform 70 is coated on the substrate 11, and covers the sidewalls of the light receiving unit 30 and the driving chip 21. The plastic encapsulation preform 70 is also located between the light receiving unit 30 and the driving chip 21. The plastic encapsulation preform 70 is located between the second plastic encapsulation block 122 and the substrate 11.

In some embodiments, the electronic component 50 is mounted on the surface of the substrate 11 away from the light receiving unit 30. The electronic component 50 may also be embedded in the plastic encapsulation preform 70 and located between the light receiving unit 30 and the substrate 11, and at this time, the plastic encapsulation preform 70 is located between the light receiving unit 30 and the substrate 11 and extends to the sidewall of the light receiving unit 30. The electronic component 50 may also be embedded in the plastic encapsulated preform 70 and located between the light receiving unit 30 and the driving chip 21. The electronic component 50 may also be located on one side of the light receiving unit 30 and on the second plastic encapsulation block 122, and the electronic component 50 is not embedded in the plastic encapsulation body 12. The position of the electronic component 50 may be set according to actual needs.

In some embodiments, the first plastic encapsulation block 121 is made of at least one of epoxy resin or phenolic resin. The second plastic encapsulation block 122 is made of at least one of polyimide adhesive, ultraviolet adhesive, black adhesive, and silicone.

(3) Referring to FIG. 9, the plastic encapsulation preform 70 is solidified to obtain the first plastic encapsulation block 121. The first plastic encapsulation block 121 and the second plastic encapsulation block 122 constitute the plastic encapsulation body 12.

The plastic encapsulation preform 70 may be solidified by heating and pressure, thereby obtaining the first plastic encapsulation block 121 with stable structure and high strength in which the light receiving unit 30 and the driving chip 21 are embedded. The first plastic encapsulation block 121 is located between the second plastic encapsulation block 122 and the substrate 11. After the plastic encapsulation preform 70 is heated and solidified, the plastic encapsulation preform 70 is adhered to the second plastic encapsulation block 122.

In some embodiments, the plastic encapsulation body 12 is made of a light shielding material. For example, the light shielding material may include a black ink. By incorporating the light shielding material into the plastic encapsulation body 12, the light from the light source 22 is prevented from passing through the plastic encapsulation body 12 and being absorbed by the light receiving unit 30. Thus, interference of the light is prevented, thereby improving the accuracy of the measurement of the target object.

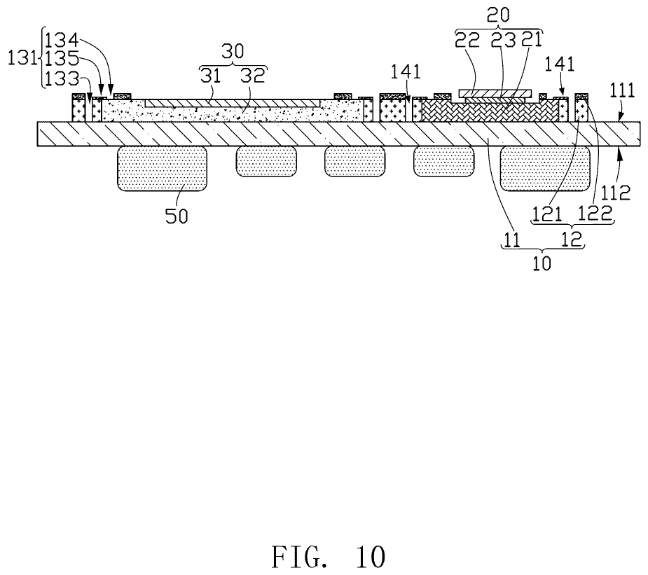

Step S3, referring to FIG. 10, a number of first channels 131 and a number of second channels 141 are defined in the plastic encapsulation body 12 of the packaging unit 210. The two ends of each of the first channels 131 extend to the substrate 11 and the non-photosensitive area 32. respectively. The two ends of each of the second channels 141 extend to the substrate 11 and the light emitting unit 20, respectively.

The solder pad of the substrate 11 is exposed from the first channel 131 and the second channel 141. The solder pad of the non-photosensitive area 32 is exposed from the first channel 131. The solder pad of the driving chip 21 of the light emitting unit 20 is exposed from the second channel 141.

In some embodiments, the first channel 131 and the second channel 141 are formed by laser drilling.

The first channel 131 includes a first portion 133, a second portion 134, and a third portion 135. The third portion 135 is connected between the first portion 133 and the second portion 134. Each of the first portion 133 and the second portion 134 extends along the thickness direction of the plastic encapsulation body 12. The third portion 135 is defined in the second plastic encapsulation block 122. The third portion 135 may be formed by drilling in a horizontal direction perpendicular to the thickness direction of the plastic encapsulation body 12, thereby forming a groove structure with an opening facing away from the substrate 11. In other embodiments, the second portion 134 is defined in the top surface of the second plastic encapsulation block 122, and no drilling treatment is performed on the second plastic encapsulation block 122.

In the embodiment, the second channel 141 has the same shape as the first channel 131.

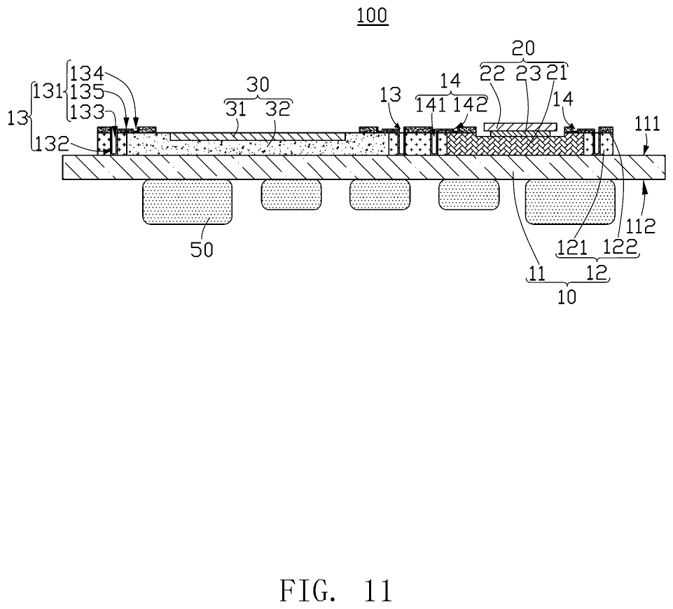

Step S4, referring to FIG. 11, the conductive material is sprayed onto the inner walls of the first channel 131 and the second channel 141, and the conductive material is solidified to form the first conductive layer 132 in the first channel 131 and the second conductive layer 142 in the second channel 141. Thus, the first hollow conductive channel 13 and second hollow conductive channel 14 are obtained.

The conductive material may be sprayed onto the inner wall of the first channel 131 and the second channel 141 in sequence by a nozzle. The conductive material may include a conductive ink. When the conductive ink is used, and the inner diameter of the first channel 131 and the second channel 141 may be less than 50 μm. If other conductive materials (such as conductive silver paste) are used, the inner diameter of the first channel 131 and the second channel 141 should be greater than 250 μm to enable the conductive silver paste to successively form inside the first channel 131 and the second channel 141. Thus, by using the conductive ink in the present disclosure, the first channel 131 and the second channel 141 may be formed with a small diameter, which is conducive to the miniaturization of the packaging structure 100.

When the conductive material includes the conductive ink, the solidification of the conductive ink includes a first solidification stage and a second solidification stage after the first solidification stage.

The first solidification stage includes irradiating the conductive ink with ultraviolet light after the conductive ink is sprayed onto the inner walls of the first channel 131 and the second channel 141, thereby pre-solidifying the conductive ink. At the first solidification stage, the ultraviolet irradiation is used to rapidly pre-solidify the conductive ink and prevent the flow of the conductive ink. The ultraviolet irradiation may be performed for a few seconds, such as for 1 second to 5 seconds.

The second solidification stage includes baking the pre-solidified conductive ink to obtain the conductive layer. After the first solidification stage, the conductive ink is pre-formed on the inner wall of the first channel 131 and the second channel 141. The conductive ink is then baked at a temperature of 60° C. to 100° C. for a duration of 0.5 h to 3 h, thereby allowing the conductive ink to be completely solidified on the inner wall of the first channel 131 and the second channel 141.

Step S5, referring to FIG. 2, a protective film 40 is coated on the surface of the second plastic encapsulation block 122 to obtain the packaging structure 100.

The protective film 40 covers the first hollow conductive channel 13 and the second hollow conductive channel 14 exposed from the second plastic encapsulation block 122. Thus, the protective film 40 blocks the conductive layer in the first channel 131 and the second channel 141, and prevents short circuits caused by the above conductive layer 32 being in contact with other components in the packaging structure 100.

After forming the protective film 40 on the packaging unit 210, the board 200 is divided along the cutting area 220 to obtain a number of packaging structures 100.

### Second Embodiment

A packaging structure 100′ is also provided according to another embodiment of the present disclosure. The difference between the packaging structure 100′ and the packaging structure 100 includes that both of the light receiving unit 30 and the driving chip 21 are located on the second surface 112, and both of the first channels 131 and the second channels 141 are defined in the substrate 11.

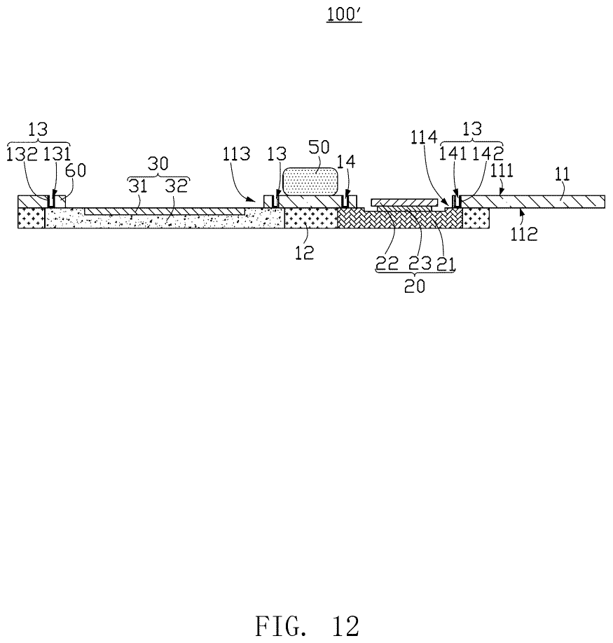

Referring to FIG. 12, the substrate 11 defines a first slot 113 and a second slot 114. The light receiving unit 30 is located on the second surface 112, and the photosensitive area 31 is exposed from the first slot 113. The non-photosensitive area 32 is adhered to the second surface 112. The first hollow conductive channel 13 extends through the substrate 11. One end of the first hollow conductive channel 13 extends to the non-photosensitive area 32. The first hollow conductive channel 13 is electrically connected to the substrate 11.

The driving chip 21 is located on the second surface 112, and the light source 22 is exposed from the second slot 114. The second hollow conductive channel 14 extends through the substrate 11 and toward the top surface of the driving chip 21.

In the embodiment, each of the first hollow conductive channel 13 and the second hollow conductive channel 14 extends along the thickness direction of the substrate 11. The solder pad of the non-photosensitive area 32 is exposed from the first channel 131. The two ends of the first hollow conductive channel 13 are electrically connected to the solder pad of the non-photosensitive area 32 and the solder pad of the first surface 111 of the substrate 11. The second hollow conductive channel 14 is electrically connected to the solder pads on the top surface of the driving chip 21 and the pad on the first surface 111 of the substrate 11, respectively.

In the embodiment, the plastic encapsulation body 12 is the first plastic encapsulation block 121, and the second plastic encapsulation block 122 is omitted. The plastic encapsulation body 12 is adhered to the sidewalls of the light receiving unit 30 and the driving chip 21 that are away from each other. The plastic encapsulation body 12 is further located between the light receiving unit 30 and the driving chip 21. There is also an adhesive layer 60 between the light receiving unit 30 and the second surface 112. The plastic encapsulation body 12 is also adhered to the second surface 112 through the adhesive layer 60.

The difference between the preparation methods of the packaging structure 100′ and the packaging structure 100 includes that when preparing the package unit 210, step (1) for forming the second plastic encapsulation block 122 in the first embodiment is omitted, and the light receiving unit 30 and the driving chip 21 are located on the second surface 112 of the substrate 11.

Furthermore, at step S2, the first channel 131 and the second channel 141 are defined in the substrate 11. Then, the conductive ink is sprayed onto the inner walls of the first channel 131 and the second channel 141. The conductive ink on the inner walls of the first channel 131 and the second channel 141 is further solidified to form the first conductive layer 132 and the second conductive layer 142.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A packaging structure, comprising:
a substrate module comprising a substrate, the substrate module defining a plurality of first hollow conductive channels and a plurality of second hollow conductive channels; and
a light emitting unit and a light receiving unit located on the substrate, the light receiving unit comprising a photosensitive area and a non-photosensitive area connected to the photosensitive area,
wherein each of the plurality of first hollow conductive channels comprises a first channel and a first conductive layer formed on an inner wall of the first channel, two ends of the first channel extend to the substrate and the non-photosensitive area, respectively, each of the plurality of first hollow conductive channels is electrically connected to the substrate and the non-photosensitive area; each of the plurality of second hollow conductive channels comprises a second channel and a second conductive layer formed on an inner wall of the second channel, two ends of the second channel extend to the substrate and the light emitting unit, respectively, and the plurality of second hollow conductive channels is electrically connected to the substrate and the light emitting unit.

2. The packaging structure according to claim 1, wherein the light emitting unit comprises a driving chip and a light source located on the driving chip, the driving chip is electrically connected to the light source; the substrate module further comprises a plastic encapsulation body, the substrate comprises a first surface and a second surface opposite to each other, each of the plastic encapsulation body, the light receiving unit, and the driving chip is located on a same surface of the first surface and the second surface, the plastic encapsulation body is at least adhered to sidewalls of the light receiving unit and the driving chip, and each of the plurality of second hollow conductive channels is electrically connected to the substrate and the driving chip.

3. The packaging structure according to claim 2, wherein the driving chip and the light receiving unit are located on the first surface, the first channel and the second channel are defined in the plastic encapsulation body; the first channel comprises a first portion, a second portion, and a third portion connected to the first portion and the second portion, each of the first portion and the second portion extends along a thickness direction of the packaging structure, one end of the first portion is connected to the substrate, and one end of the second portion is connected to the non-photosensitive area.

4. The packaging structure according to claim 3, wherein the plastic encapsulation body comprises a first plastic encapsulation block and a second plastic encapsulation block located on the first plastic encapsulation block, the first plastic encapsulation block is adhered to the sidewalls of the light receiving unit and the driving chip, the second plastic encapsulation block covers a portion of the non-photosensitive area and a portion of a top surface of the driving chip, the first portion extends through the first plastic encapsulation block and the second plastic encapsulation block, the second portion extends through the second plastic encapsulation block, and the third portion is exposed from the second plastic encapsulation block.

5. The packaging structure according to claim 4, further comprising a protective film, wherein the protective film is formed on the second plastic encapsulation block and covers the third portion.

6. The packaging structure according to claim 1, wherein each of the first conductive layer and the second conductive layer comprises a conductive material, and the conductive material comprises a conductive ink or a conductive silver paste.

7. The packaging structure according to claim 2, wherein the first channel and the second channel are defined in the substrate, the substrate further defines a first slot and a second slot, the light receiving unit is located on the second surface, the photosensitive area is exposed from the first slot, and each of the plurality of first hollow conductive channels extends through the substrate and toward the non-photosensitive area;
the driving chip is located on the second surface, the light source is exposed from the second slot, and each of the plurality of second hollow conductive channels extends through the substrate and toward a top surface of the driving chip opposite to the first surface.

8. The packaging structure according to claim 2, further comprising a plurality of electronic components, wherein the plurality of electronic components is embedded in the plastic encapsulation body, or located out of the plastic encapsulation body, or located on the substrate.

9. The packaging structure according to claim 1, wherein a thickness of the first conductive layer is greater than or equal to 500 nm.

10. A preparation method of a packaging structure, comprising:
forming a light receiving unit and a light emitting unit on a substrate of a substrate module, wherein the light receiving unit comprises a photosensitive area and a non-photosensitive area connected to the photosensitive area;
defining a plurality of first channels and a plurality of second channels in the substrate module, wherein two ends of each of the plurality of first channels extend to the substrate and the non-photosensitive area, respectively, and two ends of each of the plurality of second channels extend to the substrate and the light emitting unit, respectively; and
forming a first conductive layer on an inner wall of each of the plurality of first channels to form a first hollow conductive channel, and forming a second conductive layer on an inner wall of each of the plurality of second channels to form a second hollow conductive channel, wherein the first hollow conductive channel is electrically connected to the substrate and the non-photosensitive area, and the second hollow conductive channel is electrically connected to the substrate and the light emitting unit, thereby obtaining the packaging structure.

11. The preparation method according to claim 10, wherein the substrate module further comprises a plastic encapsulation body, the light emitting unit comprises a driving chip and a light source located on the driving chip, the substrate comprises a first surface and a second surface opposite to each other, the plastic encapsulation body, the light receiving unit, and the driving chip are located on one of the first surface and the second surface, and the plastic encapsulation body is at least adhered to sidewalls of the driving chip and the light receiving unit, and further located between the driving chip and the light receiving unit.

12. The preparation method according to claim 11, wherein the plurality of first channels and the plurality of second channels are located on the plastic encapsulation body.

13. The preparation method according to claim 12, wherein forming the light emitting unit and the light receiving unit on the substrate comprises:
forming a second plastic encapsulation block on the non-photosensitive area of the light receiving unit and the driving chip;
installing the light receiving unit and the driving chip with the second plastic encapsulation block on the first surface, wherein the substrate further comprises a plastic encapsulation preform thereon, and the plastic encapsulation preform is at least adhered to sidewalls of the light receiving unit and the driving chip; and
solidifying the plastic encapsulation preform to obtain a first plastic encapsulation block, wherein the first plastic encapsulation block and the second plastic encapsulation block form the plastic encapsulation body.

14. The preparation method according to claim 13, wherein the plastic encapsulation preform is located between the light receiving unit and the substrate, and extends to the sidewalls of the light receiving unit and the driving chip.

15. The preparation method according to claim 11, wherein the plurality of first channels and the plurality of second channels are located on the substrate.

16. The preparation method according to claim 15, wherein forming the light emitting unit and the light receiving unit on the substrate comprises:
installing the light receiving unit and the driving chip on the second surface, wherein the photosensitive area is exposed from the first slot of the substrate, the light source is exposed from the second slot of the substrate, the second surface is also provided with a plastic encapsulation preform, the plastic encapsulation preform is at least adhered to the sidewalls of the light receiving unit and the driving chip, and partially located between the light receiving unit and the driving chip; and
solidifying the plastic encapsulation preform to obtain the plastic encapsulation body.

17. The preparation method according to claim 10, wherein forming the first conductive layer and the second conductive layer further comprises:
forming a conductive material on the inner wall of each of the plurality of first channels and inner wall of each of the plurality of second channels; and
solidify the conductive material to form the first conductive layer and the second conductive layer.

18. The preparation method according to claim 17, wherein the conductive material comprises a conductive ink, solidify the conductive material comprises a first solidification stage and a second solidification stage after the first solidification stage;
the first solidification stage comprises spraying the conductive ink onto the inner wall of each of the plurality of first channels and the inner wall of each of the plurality of second channels, and irradiating the conductive ink with ultraviolet light to pre-solidify the conductive ink; and
the second solidification stage comprises baking the pre-solidified conductive ink to obtain the first conductive layer and the second conductive layer.

19. The preparation method according to claim 11, further comprising:
providing a board comprising a plurality of substrates arranged in arrays, wherein adjacent two of the plurality of substrates form a cutting area therebetween;
fabricating each of the plurality of substrates into a package unit, wherein the package unit comprises one of the plurality of substrates, the driving chip, and the plastic encapsulation body, the light emitting unit, and the light receiving unit located on the one of the plurality of substrates; and
forming the first conductive layer and the second conductive layer in the package unit to form the first hollow conductive channel and the second hollow conductive channel, respectively, and cutting the board along the cutting area to obtain a plurality of packaging structures.

20. A camera module comprising:
a lens assembly; and
a packaging structure comprising:
a substrate module comprising a substrate, the substrate module defining a plurality of first hollow conductive channels and a plurality of second hollow conductive channels; and
a light emitting unit and a light receiving unit located on the substrate, the light receiving unit comprising a photosensitive area and a non-photosensitive area connected to the photosensitive area;
wherein each of the plurality of first hollow conductive channels comprises a first channel and a first conductive layer formed on an inner wall of the first channel, two ends of the first channel extend to the substrate and the non-photosensitive area, respectively, each of the plurality of first hollow conductive channels is electrically connected to the substrate and the non-photosensitive area; each of the plurality of second hollow conductive channels comprises a second channel and a second conductive layer formed on an inner wall of the second channel, two ends of the second channel extend to the substrate and the light emitting unit, respectively, the plurality of second hollow conductive channels is electrically connected to the substrate and the light emitting unit, and the lens assembly is located on the substrate module.
